(19) United States
(12) Patent Application Publication
(10) Pub. No.: US 2021/0408479 A1
(43) Pub. Date: Dec. 30, 2021

(54) FLEXIBLE PANEL AND MANUFACTURING METHOD THEREFOR

(71) Applicant: SHENZHEN ROYOLE TECHNOLOGIES CO., LTD., Shenzhen (CN)

(72) Inventors: Ze YUAN, Shenzhen (CN); Haojun LUO, Shenzhen (CN); Jiahao KANG, Shenzhen (CN)

(21) Appl. No.: 17/353,082

(22) Filed: Jun. 21, 2021

(30) Foreign Application Priority Data
Jun. 24, 2020 (CN) 202010587443.0

(51) Int. Cl. H01L 51/52; H01L 51/56

(52) U.S. Cl. CPC H01L 51/5253; H01L 2251/5338; H01L 51/56

(57) ABSTRACT

The present disclosure discloses a flexible panel, including a base and a plurality of display modules, where the base includes a plurality of island regions arranged at intervals and a plurality of bridging regions separately used for connecting two adjacent island regions of the plurality of island regions, the plurality of display modules are arranged on the plurality of island regions respectively, two adjacent display modules of the plurality of display modules are connected by an electrical connector, and the plurality of electrical connectors are arranged on the plurality of bridging regions respectively; and each of the display modules includes a display circuit and a thin-film protection layer, and the thin-film protection layer covers the display circuit.

### TECHNICAL FIELD

The present disclosure relates to the field of display technologies, and in particular, to a flexible panel and a manufacturing method therefor.

### BACKGROUND

With the continuous development of electronic display technologies, flexible display apparatuses become a new generation of display technologies with development potential due to their many advantages such as light weight, small thickness, and bendable performance. Flexible screens have broad application prospects in the fields such as biomedicine, flexible display, and intelligent wearable devices due to their extensibility, and flexible panels are an important part of flexible screens.

At present, most of the mainstream flexible panels are implemented by directly preparing a thin-film protection layer as a whole surface on a base provided with light-emitting elements, so as to protect the light-emitting elements. However, this thin-film protection layer cannot meet packaging requirements of stretchable flexible panels.

### SUMMARY

The embodiments of the present disclosure provide a flexible panel and a manufacturing method therefor, so as to solve the above-mentioned problem of low deformation performance of an existing flexible panel.

In a first aspect, an embodiment of the present disclosure provides a flexible panel, including a base and a plurality of display modules, where the base includes a plurality of island regions arranged at intervals and a plurality of bridging regions separately used for connecting two adjacent island regions of the plurality of island regions, the plurality of display modules are arranged on the plurality of island regions respectively, two adjacent display modules of the plurality of display modules are connected by an electrical connector, and the plurality of electrical connectors are arranged on the plurality of bridging regions respectively; and each of the display modules includes a display circuit and a thin-film protection layer, and the thin-film protection layer covers the display circuit.

In an embodiment, the display circuit includes a pixel circuit and a light-emitting element arranged on the pixel circuit and driven by the pixel circuit.

In an embodiment, a side surface of the light-emitting element falls within an upper surface of the pixel circuit.

In an embodiment, the thin-film protection layer includes a first inorganic layer, and the first inorganic layer covers an upper surface and a side surface of the light-emitting element.

In an embodiment, the thin-film protection layer further includes a first organic layer, and the organic layer covers an upper surface of the first inorganic layer.

In an embodiment, the first organic layer further covers a side surface of the first inorganic layer.

In an embodiment, the thin-film protection layer further includes a second inorganic layer and a second organic layer; and the first inorganic layer, the first organic layer, the second inorganic layer, and the second organic layer are stacked.

In an embodiment, the second organic layer covers a side surface of the second inorganic layer.

In an embodiment, the base is made of a flexible and stretchable material.

In an embodiment, each of the bridging regions has a curved shape and is stretchable and deformable.

In an embodiment, the first organic layer and the second organic layer are photosensitive organic layers.

In an embodiment, the photosensitive organic layers are made of an acrylic material.

In a second aspect, an embodiment of the present disclosure provides a manufacturing method for a flexible panel, including: forming a base on a rigid substrate through deposition, the base being flexible; performing patterned etching on the base to form a plurality of island regions arranged at intervals and a plurality of bridging regions separately used for connecting two adjacent island regions of the plurality of island regions; forming a pixel circuit at each of the island regions; forming an electrical connector at each of the bridging regions, two adjacent display modules of the plurality of display modules being connected by the electrical connector; forming a light-emitting element on each of the pixel circuits, the light-emitting element being electrically connected to the pixel circuit; and forming a thin-film protection layer on each of the light-emitting elements.

In an embodiment, the forming a thin-film protection layer on each of the light-emitting elements includes: depositing a first inorganic layer on the base to cover the light-emitting element; etching the first inorganic layer, and depositing and patterning a first organic layer on the first inorganic layer; depositing a second inorganic layer on the first organic layer; and etching the second inorganic layer, and depositing and patterning a second organic layer on the second inorganic layer.

In an embodiment, the first organic layer or the second organic layer or both are photosensitive organic layers.

In an embodiment, the etching the first inorganic layer, and depositing and patterning a first organic layer on the first inorganic layer includes: depositing and patterning the first organic layer on the first inorganic layer; and using the first organic layer as a mask to etch the first inorganic layer, so that projections of the first organic layer and the first inorganic layer in the island region overlap.

In an embodiment, the etching the second inorganic layer, and depositing and patterning a second organic layer on the second inorganic layer includes: depositing and patterning the second organic layer on the second inorganic layer; and using the second organic layer as a mask to etch the second inorganic layer, so that projections of the second organic layer and the second inorganic layer in the island region overlap.

In an embodiment, the etching the first inorganic layer, and depositing and patterning a first organic layer on the first inorganic layer includes: etching the first inorganic layer by using a mask; and depositing and patterning the first organic layer on the first inorganic layer after the first inorganic layer is etched, so that the first organic layer covers an upper surface and a side surface of the first inorganic layer.

In an embodiment, the etching the second inorganic layer, and depositing and patterning a second organic layer on the second inorganic layer includes: etching the second inorganic layer by using a mask; and depositing and patterning the second organic layer on the second inorganic layer after the second inorganic layer is etched, so that the second organic layer covers an upper surface and a side surface of the second inorganic layer.

Compared with the existing technologies, in the flexible panel disclosed in the embodiments of the present disclosure, a thin-film protection layer composed of an inorganic material and an organic material is manufactured on a light-emitting element on each display module, and the thin-film protection layer does not exist at a bridging region between two adjacent island regions. Therefore, when the flexible panel is stretched or deformed by an external force, the thin-film protection layer on each display module alone is not damaged by the external force and still plays the original protective effect on a display circuit, thereby greatly improving the stretching or deformation performance of the flexible panel.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following descriptions show some embodiments of this disclosure, and a person of ordinary skill in the art may still derive others drawings from these accompanying drawings without creative efforts.

FIG. 1 is a schematic structural diagram illustrating a flexible panel disclosed in an embodiment of the present disclosure;

FIG. 2 is a schematic diagram of a cross-sectional structure at I-I in the flexible panel shown in FIG. 1;

FIG. 3a and FIG. 3b are flowcharts illustrating manufacture of the flexible panel having the cross-sectional structure shown in FIG. 2 as disclosed in an embodiment of the present disclosure;

FIG. 4 is a specific flowchart illustrating the manufacturing method for the flexible panel shown in FIG. 3b;

FIG. 5a to FIG. 5h are schematic diagrams illustrating the structure corresponding to the manufacturing method shown in FIG. 4;

FIG. 6 is another specific flowchart illustrating the manufacturing method for the flexible panel shown in FIG. 3b; and

FIG. 7a to FIG. 7h are schematic diagrams illustrating the structure corresponding to the manufacturing method shown in FIG. 6.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some rather than all embodiments of the present disclosure. All other embodiments obtained by a person of ordinary skill in the art based on the embodiments of the present disclosure without creative efforts shall fall within the protection scope of the present disclosure.

The terms “first”, “second” and the like in the specification and the claims of the present disclosure as well as the accompanying drawings are used to distinguish between different objects but not describe a specific sequence. In addition, the terms “including” and “having” and any other variations thereof are intended to cover a non-exclusive inclusion. For example, a process, a method, a system, a product, or a device that includes a series of steps or units is not limited to the listed steps or units, but optionally further includes an unlisted step or unit, or optionally further includes another inherent step or unit of the process, the method, the product, or the device.

In the description of the present disclosure, it should be noted that, unless otherwise specified and defined, the terms “mount”, “connected with”, “connected to” should be comprehended in a broader sense. For example, these terms may be comprehended as being fixedly connected, detachably connected, or integrally connected; or mechanically connected; or directly connected or indirectly connected through an intermediate medium, or in internal communication between two elements. A person of ordinary skill in the art may understand specific meanings of the preceding terms in the present disclosure based on a specific situation. In addition, the terms “including” and “having” and any other variations thereof are intended to cover a non-exclusive inclusion.

Flexible screens have certain flexibility and extensibility while maintaining conventional display functions. Therefore, they have been rapidly developed and widely used, and are made into stretchable electronic apparatuses especially in the fields of biomedicine, intelligent wearable devices, flexible displays, health care and military, featuring broad application prospects. At present, a stretching function of a flexible screen is mainly realized by an “island-bridge structure” on its flexible panel. “Island” refers to each display module in the flexible panel. The display module is provided with a display circuit and a thin-film protection layer. When the flexible panel is deformed, the thin-film protection layer does not deform and can still work. “Bridge” refers to an electrical connector with a stretchable function that is formed by deforming a conductive material. The electrical connector is configured to transmit electrical signals to a light-emitting element in each display circuit through a pixel circuit in the display circuit, and may be, for example, a U-shaped wire, a horseshoe-shaped wire, and a Z-shaped wire. When the flexible panel is deformed, the shape of the electrical connector changes accordingly. Specific implementations of the flexible panel of the present disclosure are described below in detail with reference to the accompanying drawings.

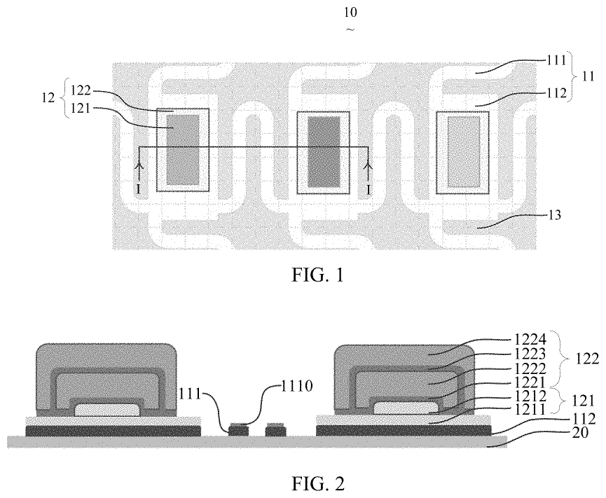

FIG. 1 is a schematic structural diagram illustrating a flexible panel disclosed in an embodiment of the present disclosure. As shown in FIG. 1, the flexible panel 10 includes a base 11 and a plurality of display modules 12.

The base 11 includes a plurality of island regions 112 arranged at intervals and a plurality of bridging regions 111 used for connecting two adjacent island regions 112 of the plurality of island regions 112. The plurality of display modules 12 are arranged on the plurality of island regions 112 respectively, i.e., each of the island regions 112 is provided with one display module 12. Two adjacent display modules 12 of the plurality of display modules 12 are connected by an electrical connector (1110, see FIG. 2), and the plurality of electrical connectors are arranged on the plurality of bridging regions 111 respectively. Each of the display modules 12 includes a display circuit 121 and a thin-film protection layer 122, and the thin-film protection layer 122 covers the display circuit 121.

The base 11 is made of a flexible and stretchable material, such as low modulus polydimethylsiloxane, elastic polyimide, polyurethane, and other elastic materials, which is not specifically limited in the embodiment, as long as it can meet deformation performance required by the design of the flexible panel 10.

A beneficial effect of the embodiment lies in that adjacent island regions 112 of the base 11 are connected by the bridging regions 111. The stretchable and deformable electrical connector formed of a conductive material is disposed on the bridging region 111. Therefore, when the base 11 is pulled or bent by an external force, the electrical connector disposed on the bridging region 111 can deform together with the bridging region under the action of the external force, so that a distance between adjacent island regions 112 increases, thereby making the flexible panel 10 have stretchable performance. During this period, the electrical connector provides electrical signals for the display circuit 121 in the display module 12. In addition, the display circuits 121 of the display modules 12 are protected independently of each other, and the display modules 12 do not significantly deform along with deformation of the base 11 due to their own rigid structure. Therefore, even if the base 11 is deformed by an external force, the display modules 12 are not affected by the external force to significantly deform, and can maintain stability of their own structure. Because the thin-film protection layer 122 covers the display circuit 121 of the display module 12 and has no significant deformation, but does not cover the bridging region 111 that is stretched by an external force, the thin-film protection layer 122 is not stretched or torn, and does not become a resistance during the stretching process of the flexible panel 10. The thin-film protection layer 122 is protected and remains intact during the stretching process.

The thin-film protection layer 122 of the display module 12 is made of a material with a high elastic modulus, such as polyimide, high elastic modulus silicone rubber, polymethyl methacrylate, and other high elastic materials, which is not specifically limited in the embodiment, so that an elastic modulus of the display module 12 is greater than that of the electrical connector. In this way, when the flexible panel 10 is in a stretched state under the action of an external force, the electrical connector deforms accordingly, and the display module 12 with a higher elastic modulus can still remain unchanged, so that the display circuit 121 and the thin-film protection layer 122 of the display module 12 are affected as little as possible by the deformation force, thereby playing a protective role on the display circuit 121 of the display module 12.

The display circuit 121 in the display module 12 is further connected to an external control chip through the electrical connector. Specifically, the electrical connector is electrically connected to the external control chip, and transmits electrical signals to the display circuit 121 of each display module 12 under the control of the external chip.

Specifically, a material used to form the electrical connector includes any one or more of the following conductive materials: a metal material, a carbon nanomaterial, a conductive polymer, and an ion conductor material, etc. If the conductive material is a metal material, it may be an electrical connector made of gold, silver, copper, aluminum, molybdenum, chromium, or other metal with relatively good conductivity, or an electrical connector made of alloy metal with conductivity meeting design requirements. If the conductive material is a metal nanomaterial, it may be an electrical connector made of a metal nanomaterial such as a metal nanowire, nanoparticles, a nanosheet, or a nanobelt. If the conductive material is a carbon nanomaterial, it may be an electrical connector made of a carbon nanomaterial such as graphene, multilayer graphite, a carbon nanotube, or a carbon nanobelt. If the conductive material is a liquid metal material, it may be an electrical connector made of a gallium-containing alloy; or the conductive material may alternatively be made of a conductive polymer, an ion conductor material, etc., which is not specifically limited in the embodiments of the present disclosure.

The embodiment has the following beneficial effects: When the flexible panel 10 is deformed, because the elastic modulus of the display module 12 is greater than an elastic modulus of the base 11, the display circuit 121 and the thin-film protection layer 122 of the display module 12 are affected as little as possible by a deformation force, so that the display circuit 121 of the display module 12 can be protected, i.e., the thin-film protection layer 122 and the display circuit 121 can be protected from damage when the base 11 is deformed. Moreover, because the electrical connector can continue to transmit electrical signals at this time, it is ensured that the flexible panel 10 can work stably during the deformation process.

FIG. 2 is a schematic diagram illustrating a cross-sectional structure at I-I in the flexible panel shown in FIG. 1. As shown in FIG. 2, each display circuit 121 includes a pixel circuit 1211 and a light-emitting element 1212. The light-emitting element 1212 is electrically connected to the pixel circuit 1211 and disposed on the pixel circuit 1211. Electrical signals are transmitted between two adjacent pixel circuits 1211 through an electrical connector 1110 on the bridging region 111, so that the light-emitting element 1212 is driven by the electrical signals transmitted by the pixel circuits 1211. In addition, the display circuit 121 arranged on the island region 112 of the base 11 is covered with the thin-film protection layer 122, and each thin-film protection layer 122 separately vapor-deposited on the light-emitting element 1212 protects the display circuit 121 protection, so as to prevent external moisture or dust from contacting the light-emitting element 1212, thereby ensuring normal operation of the light-emitting element 1212. The thin-film protection layer 122 sequentially includes a first inorganic layer 1221, a first organic layer 1222, a second inorganic layer 1223, and a second organic layer 1224 along a direction that faces away from the light-emitting element 1212. In other words, the thin-film protection layer 122 includes the first inorganic layer 1221, the first organic layer 1222, the second inorganic layer 1223, and the second organic layer 1224 which are stacked in sequence.

The embodiment has the following beneficial effects: A side surface of the light-emitting element 1212 of the display circuit 121 is located within a periphery of an upper surface of the pixel circuit 1211; i.e., a projection area of the light-emitting element 1212 on the island region 112 is less than a projection area of the pixel circuit 1211 on the island region 112. In this way, manufacturing complexity is reduced during the manufacturing process. Optionally, the projection area of the light-emitting element 1212 on the island region 112 may alternatively be equal to or greater than the projection area of the pixel circuit 1211 on the island region 112. In this way, the thin-film protection layer 122 may cover both the light-emitting element 1212 and the pixel circuit 1211, so that the pixel circuit 1211 can also isolate interference from external moisture.

The flexible panel 10 is arranged on a rigid substrate 20 during its manufacturing process to facilitate pattern etching and other operations. After the flexible panel 10 is manufactured, the rigid substrate 20 is separated from the flexible panel 10 by using a method of laser ablation or removal of a connecting film layer between the rigid substrate 20 and the flexible panel 10.

The thin-film protection layer 122 includes two inorganic layers arranged at intervals and two organic layers arranged at intervals. The number of inorganic layers arranged at intervals and the number of organic layers arranged at intervals may also be set based on actual needs. For example, one inorganic layer and two organic layers are provided, or another number of layers may be set, which is not specifically limited in the embodiments of the present disclosure.

The first inorganic layer 1221 covers an upper surface and a side surface of the light-emitting element 1212; the first organic layer 1222 covers an upper surface of the first inorganic layer 1221, and a projection of the first organic layer 1222 on the base 11 and a projection of the first inorganic layer 1221 on the base 11 overlap; and the second organic layer 1224 covers an upper surface of the second inorganic layer 1223, and a projection of the second organic layer 1224 on the base 11 and a projection of the second inorganic layer 1223 on the base 11 overlap. Optionally, the first inorganic layer 1221 covers an upper surface and a side surface of the light-emitting element 1212; the first organic layer 1222 covers an upper surface and a side surface of the first inorganic layer 1221, and a projection area of the first inorganic layer 1221 on the base 11 is less than a projection area of the first organic layer 1222 on the base 11; and the second organic layer 1224 covers an upper surface and a side surface of the second inorganic layer 1223, and a projection area of the second inorganic layer 1223 on the base 11 is less than a projection area of the second organic layer 1224 on the base 11. These two manners have their own advantages. The former has lower process difficulty, and the latter provides stronger protection to the light-emitting element 1212. The thin-film protection layer 122 may be implemented by any one of the manners, which is not specifically limited in the embodiments of the present disclosure.

In the embodiment of the present disclosure, the light-emitting element 1212 may be an organic light-emitting diode (OLED) or another light-emitting element capable of emitting light under driving of an electrical signal, which is not specifically limited in the embodiments of the present disclosure.

The first inorganic layer 1221 and the second inorganic layer 1223 each include one inorganic material or a mixture of a plurality of inorganic materials. For example, one or a mixture of two inorganic materials of silicon nitride (SiNx) and silicon oxide (SiOx) used on the flexible panel may be selected to manufacture the first inorganic layer 1221 and the second inorganic layer 1223, or another inorganic material with a similar characteristic may alternatively be selected to manufacture the first inorganic layer 1221 and the second inorganic layer 1223, which is not specifically limited in the embodiments of the present disclosure.

The first organic layer 1222 and the second organic layer 1224 each include one organic material or a mixture of a plurality of organic materials. The organic material is a photosensitive organic material, which may be used as a photosensitive organic layer in the flexible panel 10, and features water-oxygen blocking and less gas release after curing. For example, one or a mixture of a plurality of organic materials such as transparent polyimide, silica gel, organosiloxane, and Parylene is used to manufacture the first organic layer 1222 and the second organic layer 1224, or another organic material with a similar characteristic may alternatively be selected to manufacture the first organic layer 1222 and the second organic layer 1224, which is not specifically limited in the embodiments of the present disclosure. In an unlimited embodiment, the photosensitive organic layer is an acrylic material.

The embodiment has the following beneficial effects: The thin-film protection layer 122 formed of an inorganic material and an organic material is manufactured on the display circuit 121 of each display module 12, and the thin-film protection layer does not exist on the bridging region 111. Therefore, when the flexible panel 10 is stretched or deformed by an external force, the bridging region 111 between the island regions 112 accordingly enters a deformed state such as a stretched or bent state, and the display circuit 121 and the thin-film protection layer 122 of the display module 12 are not damaged by the external force, so that the thin-film protection layer 122 can still play the original protective effect on the light-emitting element 1212 of the display circuit 121 when the flexible panel 10 is in the deformed state such as the stretched or bent state, thereby greatly improving the deformation performance of the flexible panel 10.

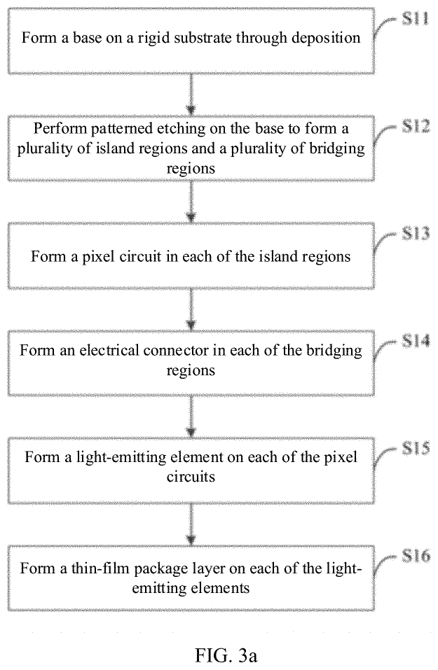

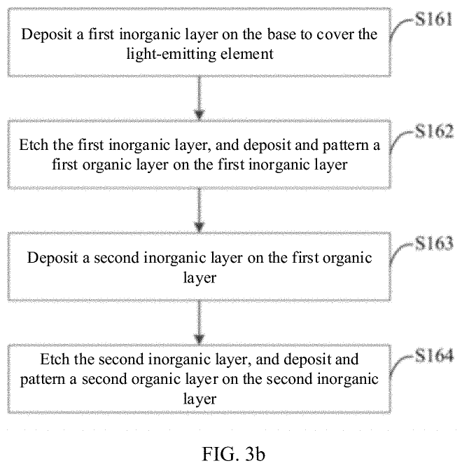

FIG. 3a and FIG. 3b are flowcharts illustrating manufacture process of the flexible panel having the cross-sectional structure shown in FIG. 2 as disclosed in an embodiment of the present disclosure. As shown in FIG. 3a, a manufacturing method for the flexible panel 10 includes at least the following steps.

S11: a base is formed on a rigid substrate through deposition.

The base 11 is made of a flexible and stretchable material, such as low modulus polydimethylsiloxane, elastic polyimide, polyurethane, and other elastic materials, which is not specifically limited in the embodiment, as long as it can meet deformation performance required by the design of the flexible panel 10.

The flexible panel 10 is arranged on the rigid substrate 20 during its manufacturing process to facilitate pattern etching and other operations. After the flexible panel 10 is manufactured, the rigid substrate 20 is separated from the flexible panel 10 by using laser ablation or removal of a connecting film layer.

S12: the base is patterned by etching to form a plurality of island regions and a plurality of bridging regions.

After a flexible base is deposited on the rigid substrate 20 as a whole surface, pattern etching is performed on the flexible base, so that only a plurality of island regions 112 arranged at intervals and a plurality of bridging regions 111 for connecting two adjacent island regions 112 of the plurality of island regions 112 are retained on the base 11.

S13: a pixel circuit is formed at each of the island regions.

After only the plurality of island regions 112 and the plurality of bridging regions 111 are retained in the base 11, the pixel circuit 1211 is arranged on each of the island regions 112.

S14: an electrical connector is formed at each of the bridging regions.

After only the plurality of island regions 112 and the plurality of bridging regions 111 are retained in the base 11, the electrical connector 1110 is disposed in each bridging region 111 to connect two adjacent pixel circuits 1211.

The sequence of S13 and S14 may be reversed, i.e., the electrical connector 1110 may be formed before the pixel circuit 1211; or S13 and S14 may be performed simultaneously, i.e., the electrical connector 1110 and the pixel circuit 1211 are formed simultaneously.

S15: a light-emitting element is formed on each of the pixel circuits.

After the pixel circuit 1211 is formed on the island region 112, the light-emitting element 1212 is provided and electrically connected to the pixel circuit 1211, and the light-emitting element 1212 is arranged on the pixel circuit 1211. Electrical signals are transmitted between two adjacent pixel circuits 1211 through an electrical connector 1110 on the bridging region 111, so that the light-emitting element 1212 is driven by the electrical signals transmitted by the pixel circuits 1211.

In the embodiment of the present disclosure, the light-emitting element 1212 may be an OLED or another light-emitting element capable of emitting light under driving of an electrical signal, which is not specifically limited in the embodiments of the present disclosure.

S16: a thin-film protection layer is formed on each of the light-emitting elements.

After the display circuit 121 including the pixel circuit 1211 and the light-emitting element 1212 is formed on the island region 112 of the base 11, the thin-film protection layer 122 is separately manufactured on each light-emitting element 1212 to protect the display circuit 121 protection, and prevents external moisture or dust from contacting the light-emitting element 1212, thereby ensuring normal operation of the light-emitting element 1212. The thin-film protection layer 122 includes an inorganic layer formed of an inorganic material and an organic layer formed of an organic material, and the bridging region 111 is not provided with the thin-film protection layer 122.

Specifically, S16 further includes at least the following steps.

S161: a first inorganic layer is deposited on the base to cover the light-emitting element.

After the display circuit 121 is formed on the island region 112 of the base 11, the first inorganic layer 1221 formed of an inorganic material is deposited on an entire surface on one side provided with the display circuit 121 of the base 11, to cover the light-emitting element 121, i.e., the first inorganic layer 1221 covers entire surfaces of the bridging region 111 and the island region 112 of the base 11.

The first inorganic layer 1221 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the first inorganic layer 1221, or another inorganic material with a similar characteristic may alternatively be selected to manufacture the first inorganic layer 1221, which is not specifically limited in the embodiments of the present disclosure.

S162: the first inorganic layer is etched, and a first organic layer is deposited and patterned on the first inorganic layer.

The manufactured first organic layer 1222 may cover only an upper surface of the first inorganic layer 1221, or cover both the upper surface and a side surface of the first inorganic layer 1221. The former has lower process difficulty, while the latter provides stronger protection to the light-emitting element 1212.

S163: a second inorganic layer is deposited on the first organic layer.

After the first organic layer 1222 covers the first inorganic layer 1221, a second inorganic layer 1223 formed of an inorganic material is further deposited on an entire surface on one side provided with the display circuit 121 of the base 11, to cover the first organic layer 1222 and the first inorganic layer 1221, i.e., the second inorganic layer 1223 covers entire surfaces of the bridging region 111 and the island region 112 of the base 11.

Specifically, the second inorganic layer 1223 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the second inorganic layer 1223, or another inorganic material with a similar characteristic may alternatively be selected to manufacture the second inorganic layer 1223, which is not specifically limited in the embodiments of the present disclosure.

S164: the second inorganic layer is etched, and a second organic layer is deposited and patterned on the second inorganic layer.

The manufactured second organic layer 1224 may cover only an upper surface of the second inorganic layer 1223, or cover both the upper surface and a side surface of the second inorganic layer 1223. The former has lower process difficulty, while the latter provides stronger protection to the light-emitting element 1212.

The embodiment has the following beneficial effects: After pattern etching has been performed on the entire flexible base and only the plurality of bridging regions 111 and the plurality of island regions 112 are retained, the display circuits 121 are provided on the island regions 112, a thin-film protection layer 122 is manufactured on each display circuit 121 to protect the light-emitting element 1212 of the display circuit 121, and the thin-film protection layer 122 does not exist on the bridging region 111 between any two adjacent display circuits 121. Therefore, when the flexible panel 10 is stretched or deformed by an external force, the bridging region 111 between the display modules 12 accordingly enters a deformed state such as a stretched or bent state, and the display circuit 121 and the thin-film protection layer 122 of the display module 12 are not damaged by the external force, so that the thin-film protection layer 122 can still play the original protective effect on the light-emitting element 1212 of the display circuit 121 when the flexible panel 10 is in the deformed state such as the stretched or bent state, thereby greatly improving the deformation performance of the flexible panel 10.

Further, after the bridging region 111 of the base 11 is provided with an electrical connector 1110, a corresponding protection layer may further be provided on the electrical connector 1110 to protect the electrical connector 1110. It can be understood that, the protection layer on the electrical connector 1110 is different from the thin-film protection layer 122 on the light-emitting element 121. Specifically, the protection layer on the electrical connector 1110 has higher deformation performance such as stretching or bending performance, and can change with stretching, bending, or other deformation of the flexible panel 10 without damage.

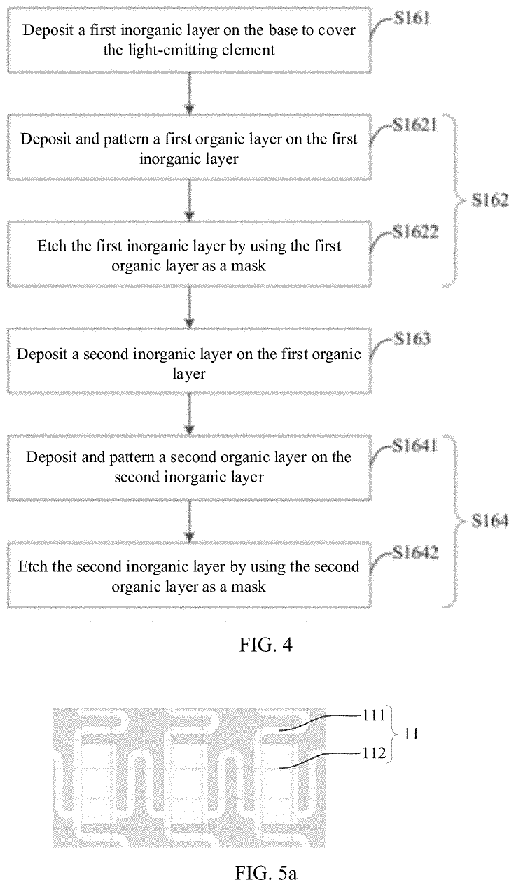

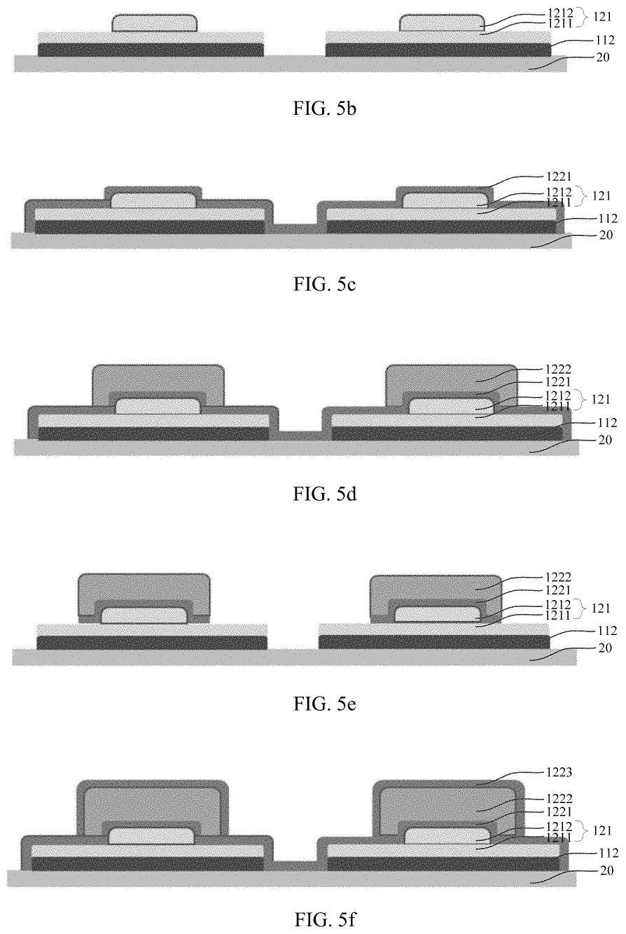

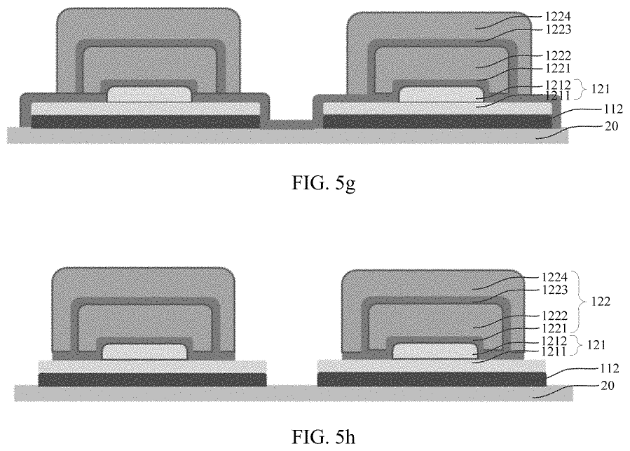

FIG. 4 is a specific flowchart illustrating a manufacturing method for the flexible panel shown in FIG. 3b, where S1621 and S1622 are a detailed execution process of S162 in FIG. 3b, and S1641 and S1642 are a detailed execution process of S164 in FIG. 3b. FIG. 5a to FIG. 5h are schematic diagrams illustrating a structure corresponding to the manufacturing method shown in FIG. 4.

FIG. 5a corresponds to S11 to S14. To be specific, after the flexible base is deposited on the rigid substrate 20 as a whole surface, pattern etching is performed on the flexible base, so that only a plurality of island regions 112 arranged at intervals and a plurality of bridging regions 111 for connecting two adjacent island regions 112 of the plurality of island regions 112 are retained in the base 11. Then, pixel circuits 1121 and electrical connectors 1110 are formed on the island regions 112 and the bridging regions respectively. The electrical connectors 1110 are each configured to electrically connect two adjacent pixel circuits 1121.

FIG. 5b corresponds to S15. To be specific, after the pixel circuit 1211 is formed on the island region 112, the light-emitting element 1212 is provided and electrically connected to the pixel circuit 1211, and the light-emitting element 1212 is arranged on the pixel circuit 1211. Electrical signals are transmitted between two adjacent pixel circuits 1211 through the electrical connector 1110 on the bridging region 111, so that the light-emitting element 1212 is driven by the electrical signals transmitted by the pixel circuits 1211.

S161: a first inorganic layer is deposited on the base to cover the light-emitting element.

As shown in FIG. 5c, after the display circuit 121 including the pixel circuit 1211 and the light-emitting element 1212 is formed on the island region 112 of the base 11, a first inorganic layer 1221 formed of an inorganic material is deposited on an entire surface on one side provided with the display circuit 121 of the base 11, to cover the light-emitting element 1212, i.e., the first inorganic layer 1221 covers entire surfaces of the bridging region 111 and the island region 112 of the base 11.

The first inorganic layer 1221 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the first inorganic layer 1221, or another inorganic material with a similar characteristic may alternatively be selected to manufacture the first inorganic layer 1221, which is not specifically limited in the embodiments of the present disclosure.

S1621: a first organic layer is deposited and patterned on the first inorganic layer.

As shown in FIG. 5d, after the first inorganic layer 1221 is deposited on a surface provided with the light-emitting element 1212 of the base 11, the first inorganic layer 1221 is coated with the first organic layer 1222 at a position corresponding only to the island region 112 of the base 11 and covering the display circuit 121. In other words, a surface of the first inorganic layer 1221 is coated with the first organic layer 1222 only at a position correspondingly covering the light-emitting element 1212, and then the first organic layer 1222 is exposed and patterned, so as to cure and stabilize the first organic layer 1222.

The first organic layer 1222 may be formed of one organic material or a mixture of a plurality of organic materials. The organic material features water-oxygen blocking and less gas release after curing. For example, one or a mixture of a plurality of organic materials such as transparent polyimide, silica gel, organosiloxane, and Parylene is used to manufacture the first organic layer 1222, or another organic material with a similar characteristic may alternatively be selected to manufacture the first organic layer 1222, which is not specifically limited in the embodiments of the present disclosure.

S1622: the first inorganic layer is etched by using the first organic layer as a mask.

As shown in FIG. 5e, after the first inorganic layer 1221 is coated with the first organic layer 1222 at the position corresponding to the island region 112, the first organic layer 1222 is used as a mask to etch the first inorganic layer 1221, so as to remove the first inorganic layer 1221 that is not covered with the first organic layer 1222 on the base 11. Therefore, each island region 112 of the base 11 has a corresponding display circuit 121, first inorganic layer 1221, and first organic layer 1222 that are separately stacked.

Further, after the etching operation on the first inorganic layer 1221, the first organic layer 1222 covers only an upper surface of the first inorganic layer 1221, and a projection of the first inorganic layer 1221 and a projection of the first organic layer 1222 on the base 11 overlap, thereby helping reduce a volume of the first inorganic layer 1221 and the first organic layer 1222.

S163: a second inorganic layer is deposited on the first organic layer.

As shown in FIG. 5f, after the first inorganic layer 1221 not covered with the first organic layer 1222 on the base 11 is removed, a second inorganic layer 1223 formed of an inorganic material is further deposited on an entire surface on one side provided with the display circuit 121 of the base 11, to cover side surfaces of both the first organic layer 1222 and the first inorganic layer 1221, i.e., the second inorganic layer 1223 covers entire surfaces of the bridging region 111 and the island region 112 in the base 11.

The second inorganic layer 1223 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the second inorganic layer 1223, or another inorganic material with a similar characteristic may alternatively be selected to manufacture the second inorganic layer 1223, which is not specifically limited in the embodiments of the present disclosure.

S1641: a second organic layer is deposited and patterned on the second inorganic layer.

As shown in FIG. 5g, after the second inorganic layer 1223 is deposited on a surface provided with the display circuit 121 of the base 11, the second inorganic layer 1223 is further coated with the second organic layer 1224 at a position corresponding only to the island region 112 of the base 11. In other words, a surface of the second inorganic layer 1223 is coated with the second organic layer 1224 only at a position correspondingly covering the island region 112, and then the second organic layer 1224 is exposed and patterned, so as to cure and stabilize the second organic layer 1224.

The second organic layer 1224 may be formed of one organic material or a mixture of a plurality of organic materials. The organic material features water-oxygen blocking and less gas release after curing. For example, one or a mixture of a plurality of organic materials such as transparent polyimide, silica gel, organosiloxane, and Parylene is used to manufacture the second organic layer 1224, or another organic material with a similar characteristic may alternatively be selected to manufacture the second organic layer 1224, which is not specifically limited in the embodiments of the present disclosure.

S1642: the second inorganic layer is etched by using the second organic layer as a mask.

As shown in FIG. 5h, after the second inorganic layer 1223 is coated with the second organic layer 1224 at a position corresponding only to the island region 112, the second organic layer 1224 is used as a mask to etch the second inorganic layer 1223, so as to remove the second inorganic layer 1223 that is not covered with the second organic layer 1224 on the base 11. Therefore, each island region 112 of the base 11 corresponds to a separately arranged display module 12, and each display module 12 includes a display circuit 121, a first inorganic layer 1221, a first organic layer 1222, a second inorganic layer 1223, and a second organic layer 1224 that are stacked, where the first inorganic layer 1221, the first organic layer 1222, the second inorganic layer 1223, and the second organic layer 1224 constitute the thin-film protection layer 122. Further, after the etching operation on the second inorganic layer 1223, the second organic layer 1224 covers only an upper surface of the second inorganic layer 1223, and a projection of the second inorganic layer 1223 and a projection of the second organic layer 1224 on the base 11 overlap, thereby helping reduce a volume of the second inorganic layer 1223 and the second organic layer 1224.

The embodiment has the following beneficial effects: The manufacturing method shown in FIG. 4 and the specific processes shown in FIG. 5a to FIG. 5h can reduce the process difficulty in manufacturing the flexible panel 10 by using an organic layer as a mask to etch an inorganic layer, i.e., by performing self-alignment between the organic layer and the inorganic layer. In addition, this manufacturing method makes a projection of the organic layer and that of the inorganic layer on the base overlap, thereby reducing a volume of the display module 12.

Further, the thin-film protection layer 122 formed of an inorganic material and an organic material is manufactured on the display circuit 121 of each display module 12, and the thin-film protection layer 122 does not exist on the bridging region 111. Therefore, when the flexible panel 10 is in a deformed state such as a stretched or bent state by an external force, a deformed region between the display modules 12 accordingly enters a deformed state such as a stretched or bent state, and the light-emitting element 1212 and the thin-film protection layer 122 on the display module 12 are not damaged by the external force, so that the thin-film protection layer 122 can still play the original protective effect on the light-emitting element 1212 in the display circuit 121 when the flexible panel 10 is in the deformed state such as the stretched or bent state, thereby greatly improving the deformation performance of the flexible panel 10, such as stretching or bending performance.

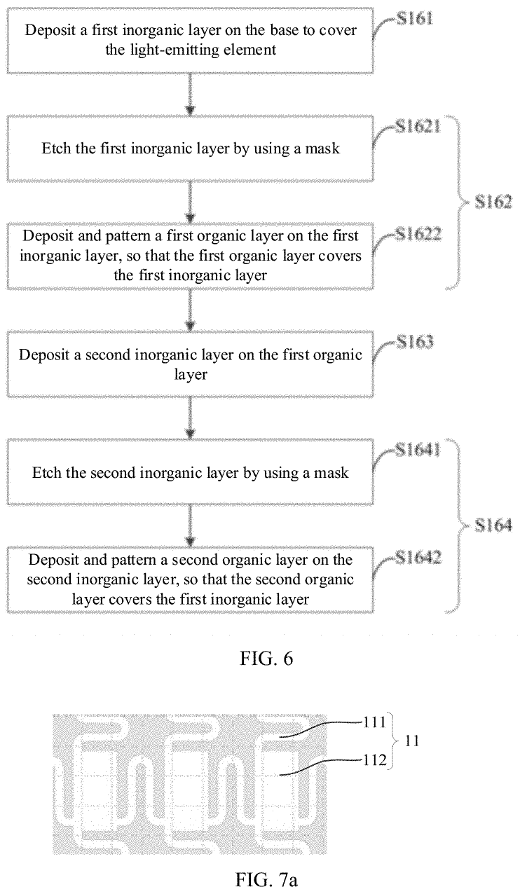

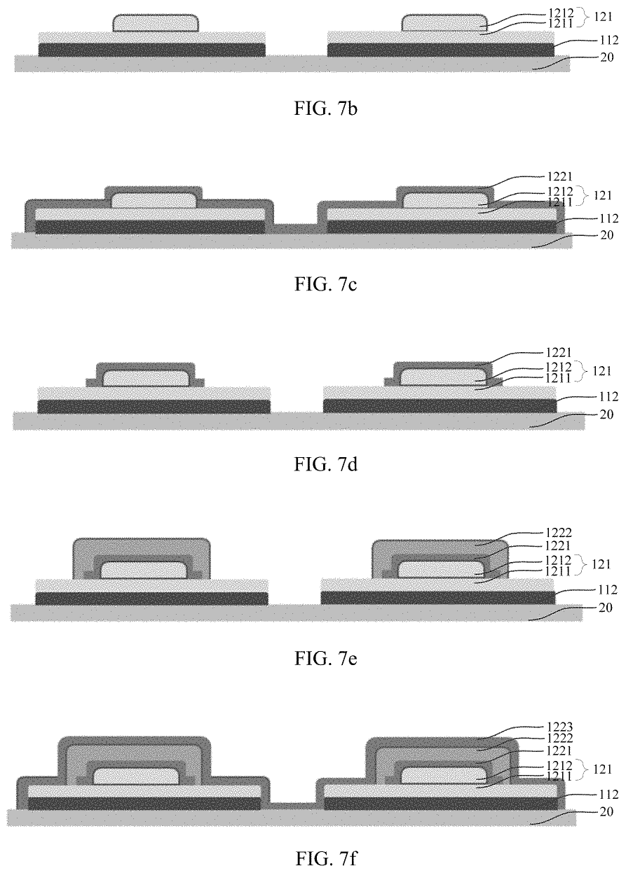

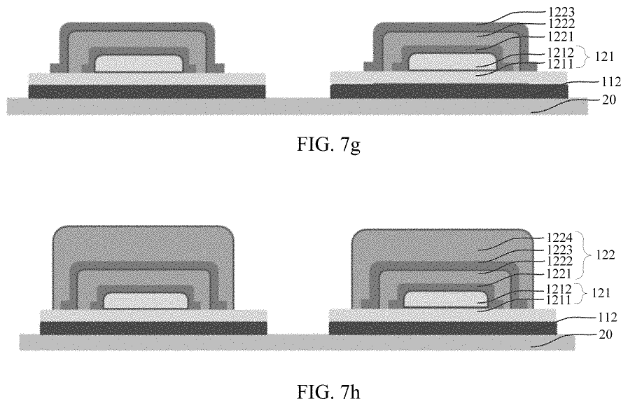

Please referring to FIGS. 6 and 7a-7h, FIG. 6 is another specific flowchart illustrating a manufacturing method for the flexible panel shown in FIG. 3b, where S1621 and S1622 are a detailed execution process of S162 in FIG. 3b, and S1641 and S1642 are a detailed execution process of S164 in FIG. 3b. FIG. 7a to FIG. 7h are schematic diagrams illustrating a structure corresponding to the manufacturing method shown in FIG. 6.

FIG. 7a corresponds to S11 to S14. To be specific, after the flexible base is deposited on the rigid substrate 20 as a whole surface, pattern etching is performed on the flexible base, so that only a plurality of island regions 112 arranged at intervals and a plurality of bridging regions 111 for connecting two adjacent island regions 112 of the plurality of island regions 112 are retained in the base 11. Then, pixel circuits 1121 and electrical connectors 1110 are formed on the island regions 112 and the bridging regions respectively. The electrical connectors 1110 are each configured to electrically connect two adjacent pixel circuits 1121.

FIG. 7b corresponds to S15. To be specific, after the pixel circuit 1211 is formed on the island region 112, the light-emitting element 1212 is provided and electrically connected to the pixel circuit 1211, and the light-emitting element 1212 is arranged on the pixel circuit 1211. Electrical signals are transmitted between two adjacent pixel circuits 1211 through the electrical connector 1110 on the bridging region 111, so that the light-emitting element 1212 is driven by the electrical signals transmitted by the pixel circuits 1211.

S161: a first inorganic layer is deposited on the base to cover the light-emitting element.

As shown in FIG. 7c, after the display circuit 121 including the pixel circuit 1211 and the light-emitting element 1212 is formed on the island region 112 of the base 11, the first inorganic layer 1221 formed of an inorganic material is deposited on an entire surface on one side provided with the display circuit 121 of the base 11, to cover the light-emitting element 1212, i.e., the first inorganic layer 1221 covers entire surfaces of the bridging region 111 and the island region 112 of the base 11.

The first inorganic layer 1221 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the first inorganic layer 1221, or another inorganic material with a similar characteristic may alternatively be selected to manufacture the first inorganic layer 1221, which is not specifically limited in the embodiments of the present disclosure.

S1621: the first inorganic layer is etched by using a mask.

As shown in FIG. 7d, after a surface of the base 11 is covered with the first inorganic layer 1221, a photo process is performed on the first inorganic layer 1221 for patterning, and a mask is used for etching to remove the first inorganic layer 1221 except a first region. The first region represents a region occupied by the first inorganic layer 1221 that covers an upper surface and a side surface of the light-emitting element 121, and a projection of the first region on the base 11 is less than an area of the island region 112. In other words, the first inorganic layer 1221 is etched to remove the first inorganic layer 1221 that does not cover the upper surface and the side surface of the light-emitting element 121.

S1622: a first organic layer is deposited and patterned on the first inorganic layer, so that the first organic layer covers the first inorganic layer.

As shown in FIG. 7e, after the first inorganic layer 1221 is etched to remove the first inorganic layer 1221 except the first region, the first inorganic layer 1221 is coated with a first organic layer 1222, i.e., a surface of the first inorganic layer 1221 is coated with the first organic layer 1222 at a position correspondingly covering the display circuit 121, and then the first organic layer 1222 is exposed and patterned, so as to cure and stabilize the first organic layer 1222.

After the first inorganic layer 1221 is coated with the first organic layer 1222, a side surface of the first inorganic layer 1221 is also covered with the first organic layer 1222, i.e., an orthographic projection area of the first organic layer 1222 on the base 11 is greater than that of the first inorganic layer 1221 on the base 11. In this way, the first organic layer 1222 can cover a sidewall of the first inorganic layer 1221 to prevent moisture or other gases from entering the thin-film protection layer 122 and affecting the performance of the light-emitting element 1212, thereby better protecting the light-emitting element 1212.

Specifically, the first organic layer 1222 may be formed of one organic material or a mixture of a plurality of organic materials. The organic material features water-oxygen blocking and less gas release after curing. For example, one or a mixture of a plurality of organic materials such as transparent polyimide, silica gel, organosiloxane, and Parylene is used to manufacture the first organic layer 1222, or another organic material with a similar characteristic may alternatively be selected to manufacture the first organic layer 1222, which is not specifically limited in the embodiments of the present disclosure.

S163: a second inorganic layer is deposited on the first organic layer.

As shown in FIG. 7f, after the first inorganic layer 1221 is coated with the first organic layer 1222, a second inorganic layer 1223 formed of an inorganic material is further deposited on an entire surface on one side provided with the display circuit 121 of the base 11, to cover the first organic layer 1222, i.e., the second inorganic layer 1223 covers an entire surface of the base 11.

Specifically, the second inorganic layer 1223 may be formed of one inorganic material or a mixture of a plurality of inorganic materials. For example, an inorganic material used on the flexible panel, including but not limited to one or a mixture of two of silicon nitride (SiNx) and silicon oxide (SiOx), may be selected to manufacture the second inorganic layer 1223, or another inorganic material with a similar characteristic may alternatively be selected to manufacture the second inorganic layer 1223, which is not specifically limited in the embodiments of the present disclosure.

S1641: the second inorganic layer is etched by using a mask.

As shown FIG. 7g, after the surface of the base 11 is covered with the second inorganic layer 1223, a photo process is performed on the second inorganic layer 1223 for patterning, and a mask is used for etching to remove the second inorganic layer 1223 except a second region. The second region represents a region occupied by the second inorganic layer 1223 that covers an upper surface and a side surface of the first organic layer 1222, and a projection of the second region on the base 11 is greater than a projection of the first region on the base 11, and less than an area of the display module 12 region. In other words, the second inorganic layer 1223 is etched to remove the second inorganic layer 1223 that does not cover the upper surface and the side surface of the first organic layer 1222.

S1642: a second organic layer is deposited and patterned on the second inorganic layer, so that the second organic layer covers the second inorganic layer.

As shown in FIG. 7h, after the second inorganic layer 1223 is etched to remove the second inorganic layer 1223 except the second region, the second inorganic layer 1223 is coated with the second organic layer 1224, i.e., a surface of the second inorganic layer 1223 is coated with the second organic layer 1224 at a position corresponding to the island region 112 and the light-emitting element 121 is covered, and then the second organic layer 1224 is exposed and patterned to cure and stabilize the second organic layer 1224.

After the second inorganic layer 1223 is coated with the second organic layer 1224, a side surface of the second inorganic layer 1223 is also covered with the second organic layer 1224, i.e., an orthographic projection area of the second organic layer 1224 on the base 11 is greater than that of the second inorganic layer 1223 on the base 11. In this way, the second organic layer 1224 can cover the side surface of the second inorganic layer 1223 to prevent moisture or other gases from entering the thin-film protection layer 122 and affecting the performance of the light-emitting element 1212, thereby better protecting the light-emitting element 1212.

Specifically, the second organic layer 1224 may be formed of one organic material or a mixture of a plurality of organic materials. The organic material features water-oxygen blocking and less gas release after curing. For example, one or a mixture of a plurality of organic materials such as transparent polyimide, silica gel, organosiloxane, and Parylene is used to manufacture the second organic layer 1224, or another organic material with a similar characteristic may alternatively be selected to manufacture the second organic layer 1224, which is not specifically limited in the embodiments of the present disclosure.

The embodiment has the following beneficial effects: According to the manufacturing method shown in FIG. 6 and the specific process shown in FIG. 7a to FIG. 7h, an upper surface and a sidewall of an inorganic layer are covered with an adjacent organic layer, so that protection provided by a thin-film protection layer 122 to a light-emitting element 1212 can be improved, thereby improving light-emitting stability of the light-emitting element 1212 in the entire flexible panel 10.

The embodiment further has the following beneficial effects: The thin-film protection layer 122 formed of an inorganic material and an organic material is formed on the display circuit 121 of each display module 12, and the thin-film protection layer 122 does not exist on the bridging region 111. Therefore, when the flexible panel 10 is in a deformed state such as a stretched or bent state by an external force, the bridging region 111 between the display modules 12 accordingly enters a deformed state such as a stretched or bent state, and the light-emitting element 1212 and the thin-film protection layer 122 of the display module 12 are not damaged by the external force, so that the thin-film protection layer 122 can still play the original protective effect on the light-emitting element 1212 when the flexible panel 10 is in the deformed state such as the stretched or bent state, thereby greatly improving the deformation performance of the flexible panel 10, such as stretching or bending performance.

As shown in FIG. 4 and FIG. 6, the two manufacturing methods based on the flexible panel in FIG. 3b have their own characteristics. In the method shown in FIG. 4, an organic layer is used as a mask in S162 and S164 to remove an inorganic layer other than the island region 112, which reduces a volume of the display module 12 while reducing process difficulty. In the method shown in FIG. 6, an upper surface and a side surface of an inorganic layer are coated with an organic layer in S162 and S164 to improve protection provided by the thin-film protection layer 122 to the light-emitting element 1212, thereby improving light-emitting stability of the light-emitting element in the flexible panel 10. In addition, the flexible panels finally manufactured by using the methods shown in FIG. 4 and FIG. 6 are each implemented by manufacturing only the thin-film protection layer 122 made of an inorganic material and an organic material on the light-emitting element 1212 on each display module 12, and the thin-film protection layer 122 does not exist on the bridging region 111 between two adjacent display circuits 121. Therefore, when the flexible panel 10 is in a deformed state such as a stretched or bent state by an external force, the thin-film protection layer 122 on each display module 12 is not damaged by the external force, and can still play the original protective effect on the light-emitting element 121, thereby greatly improving the deformation performance of the flexible panel 10, such as stretching or bending performance.

Compared with the existing technologies, in the flexible panel disclosed in the embodiments of the present disclosure, a thin-film protection layer 122 formed of an inorganic material and an organic material is vapor-deposited on a display circuit 121 of each display module 12, and the thin-film protection layer 122 does not exist on a bridging region 111 between two adjacent island regions 112. Therefore, when the flexible panel 10 is in a deformed state such as a stretched or bent state by an external force, the thin-film protection layer 122 on each display module 12 is not be damaged by the external force, and can still play the original protective effect on the light-emitting element 1212 in the display circuit 121, thereby greatly improving the deformation performance of the flexible panel 10, such as stretching or bending performance.

The flexible panel and the manufacturing method therefor disclosed in the embodiments of the present disclosure are described above in detail. Specific examples are used herein for illustration of the principles and implementations of the present disclosure. The description of the embodiments above is used to help understand the method of the present disclosure and the core idea thereof. In addition, a person of ordinary skill in the art can make changes in terms of specific implementations and scope of disclosure in accordance with the idea of the present disclosure. In conclusion, the content of the specification should not be construed as a limitation on the present disclosure.

What is claimed is:

1. A flexible panel, comprising a base and a plurality of display modules, wherein the base comprises a plurality of island regions arranged at intervals and a plurality of bridging regions connecting two adjacent island regions of the plurality of island regions, the plurality of display modules are arranged on the plurality of island regions respectively, two adjacent display modules of the plurality of display modules are connected by one of a plurality of electrical connectors, and the plurality of electrical connectors are arranged on the plurality of bridging regions respectively; and each of the display modules comprises a display circuit and a thin-film protection layer, and the thin-film protection layer covers the display circuit.

2. The flexible panel according to claim 1, wherein the display circuit comprises a pixel circuit and a light-emitting element arranged on the pixel circuit and driven by the pixel circuit.

3. The flexible panel according to claim 2, wherein an outer periphery of the light-emitting element is located within an outer periphery of the pixel circuit.

4. The flexible panel according to claim 3, wherein the thin-film protection layer comprises a first inorganic layer, and the first inorganic layer covers an upper surface and a side surface of the light-emitting element.

5. The flexible panel according to claim 4, wherein the thin-film protection layer further comprises a first organic layer, and the organic layer covers an upper surface of the first inorganic layer.

6. The flexible panel according to claim 5, wherein the first organic layer further covers a side surface of the first inorganic layer.

7. The flexible panel according to claim 4, wherein the thin-film protection layer further comprises a second inorganic layer and a second organic layer; and the first inorganic layer, the first organic layer, the second inorganic layer, and the second organic layer are stacked.

8. The flexible panel according to claim 7, wherein the second organic layer covers a side surface of the second inorganic layer.

9. The flexible panel according to claim 1, wherein the base is made of a flexible and stretchable material.

10. The flexible panel according to claim 1, wherein each of the bridging regions has a curved shape and is stretchable and deformable.

11. The flexible panel according to claim 7, wherein the first organic layer and the second organic layer are photosensitive organic layers.

12. The flexible panel according to claim 1, wherein an elastic modulus of each of the display modules is greater than an elastic modulus of each of the plurality of electrical connectors.

13. The flexible panel according to claim 11, wherein the photosensitive organic layers are made of an acrylic material.

14. A manufacturing method for a flexible panel, comprising:
forming a flexible base on a rigid substrate;
patterning the base to form a plurality of island regions arranged at intervals and a plurality of bridging regions connecting two adjacent island regions of the plurality of island regions;
forming a pixel circuit at each of the island regions;
forming an electrical connector at each of the bridging regions, two adjacent display modules of the plurality of display modules being connected by the electrical connector;
forming a light-emitting element on each of the pixel circuits, the light-emitting element being electrically connected to the pixel circuit; and
forming a thin-film protection layer on each of the light-emitting elements.

15. The manufacturing method according to claim 14, wherein the forming a thin-film protection layer on each of the light-emitting elements comprises:
forming a first inorganic layer on the base to cover the light-emitting element;
etching the first inorganic layer, and forming and patterning a first organic layer on the first inorganic layer;
forming a second inorganic layer on the first organic layer; and
etching the second inorganic layer, and forming and patterning a second organic layer on the second inorganic layer.

16. The manufacturing method according to claim 15, wherein the first organic layer or the second organic layer or both are photosensitive organic layers.

17. The manufacturing method according to claim 16, wherein the etching the first inorganic layer, and forming and patterning a first organic layer on the first inorganic layer comprises:
forming and patterning a first organic layer on the first inorganic layer; and
using the first organic layer as a mask to etch the first inorganic layer, so that projections of the first organic layer and the first inorganic layer on the island region overlap.

18. The manufacturing method according to claim 16, wherein the etching the second inorganic layer, and forming and patterning a second organic layer on the second inorganic layer comprises:
forming and patterning a second organic layer on the second inorganic layer; and
using the second organic layer as a mask to etch the second inorganic layer, so that projections of the second organic layer and the second inorganic layer on the island region overlap.

19. The manufacturing method according to claim 15, wherein the etching the first inorganic layer, and forming and patterning a first organic layer on the first inorganic layer comprises:
etching the first inorganic layer by using a mask; and
forming and patterning a first organic layer on the first inorganic layer after the first inorganic layer is etched, so that the first organic layer covers an upper surface and a side surface of the first inorganic layer.

20. The manufacturing method according to claim 15, wherein the etching the second inorganic layer, and forming and patterning a second organic layer on the second inorganic layer comprises:
etching the second inorganic layer by using a mask; and
forming and patterning a second organic layer on the second inorganic layer after the second inorganic layer is etched, so that the second organic layer covers an upper surface and a side surface of the second inorganic layer.
